(19) United States
(12) Patent Application Publication
(10) Pub. No.: US 2002/0164832 A1
(43) Pub. Date: Nov. 7, 2002

(54) Method for separating silica waveguides

(76) Inventor: Amir Mirza, Fremont, CA (US)

Correspondence Address: Dike, Bronstein, Roberts & Cushman, Intellectual Property Practice Group, EDWARDS & ANGELL, LLP, P.O. Box 9169, Boston, MA, 02209, US

(21) Appl. No.: 10/138,201

(22) Filed: May 3, 2002

Related U.S. Application Data
(60) Provisional application No. 60/288,591, filed on May 4, 2001.

(51) Int. Cl. H01L 21/00

(52) U.S. Cl. 438/31; 438/460; 438/462

(57) ABSTRACT

A method is provided for separating silica waveguides made in multiple units on a wafer at the end of fabrication. Streets are formed between adjacent waveguides by etching the IC material to a substrate. The substrate is then sawed along the streets.

### CROSS REFERENCE TO RELATED APPLICATIONS

This application claims priority to Provisional Application No. 60/288,591 filed on May 4, 2001.

### FIELD OF THE INVENTION

This invention relates to the manufacture of Nanophotonic Waveguides and more particularly the separation of the individual chips on the wafer once manufacture has been completed.

### BACKGROUND OF THE INVENTION

Conventionally, Integrated Circuit (IC) chips and structures are fabricated in multiple units on a single wafer using known IC chip fabrication techniques. At some stage, the individual IC chips must be separated from each other on the wafer once the manufacturing process has been completed. Presently, this is done by dicing, which involves sawing through the entire wafer at predetermined intervals. Such sawing through the various integrated circuit materials present on the wafer can cause stress and damage the formed IC chip structures.

Thus, there exists a need in the art for a final separation step in the manufacturing technique of integrated circuits that overcomes the above-described shortcomings.

### SUMMARY OF THE INVENTION

The subject method overcomes the deficiency of the prior art by first etching separation streets between adjacent IC chips. The streets extend through the IC chip material to a substrate forming the base for the IC chip. The base is then sawed along the streets.

The invention accordingly comprises the features of construction, combination of elements, arrangement of parts and steps for performing the method, which will be exemplified in the disclosure.

### BRIEF DESCRIPTION OF THE DRAWINGS

In the drawing figures, which are not to scale, and which are merely illustrative, and wherein like reference characters denote similar elements throughout the several views:

FIG. 1A is a side cross-sectional view of a layered structure which will be sectioned to become an optical waveguide;

FIG. 1B is a side cross-sectional view of the layered structured of FIG. 1A partially-sectioned by streets formed therein in accordance with the invention; and

FIG. 1C is a side cross-sectional view of the layered structure fully-sectioned by sawing in accordance with the invention.

### DETAILED DESCRIPTION OF THE PREFERRED EMBODIMENT

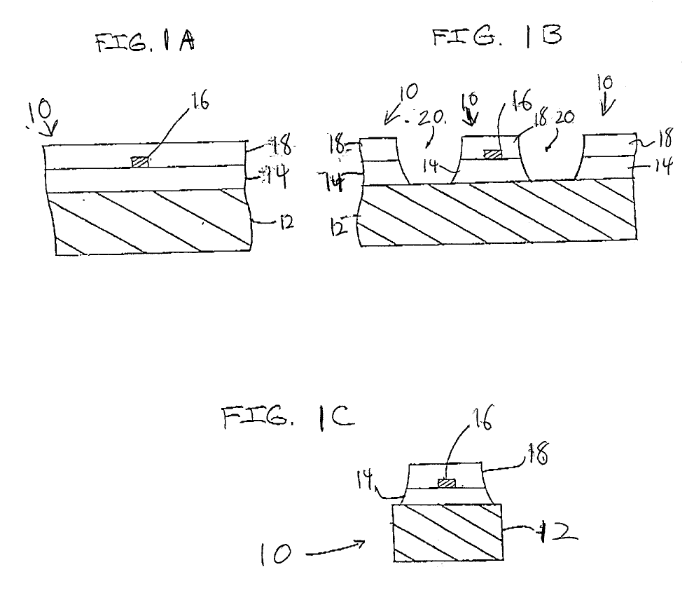

Reference is first made to FIG. 1A which shows a wafer assembly for forming an optical waveguide as is known in the art. The waveguide as shown is representative of an IC chip as known in the art. IC chip 10 includes a base or substrate 12 formed by the wafer. A thick oxide cladding layer 14 is deposited on substrate 12 as is known in the art. A circuit element, in this embodiment a waveguide core 16, by way of example, is formed, through processes known in the art such as PECVD depositing coupled with photolithographic etching. However, this is by way of example and other methods of forming an optical circuit, known in the art can be used in accordance with the present invention. Once core 16 is formed, a thick oxide cladding layer 18 is deposited over core 16. Collectively, cladding layer 14, core 16, and cladding layer 18 are the “IC material.”

In the conventional method of manufacture, circuit 10 as shown in FIG. 1A will then be sawed so that a cutting step would cut substrate wafer 12, thick oxide cladding layer 14, and thick oxide cladding layer 18 putting a stress on the functional elements, namely layers 14, 18 and core 16 as a result of the sawing.

In accordance with the present invention, as shown in FIG. 1B, streets 20 are formed between adjacent circuit structures (waveguides) 10. Streets 20 are formed by coating the surface to be etched with a photo resist material and selectively exposing and curing the photo resist material to define regions corresponding to streets 20 to be etched. The streets are then etched through layers 14 and 18, to substrate 12. As a result, in this step of the process one is left with a wafer substrate 12 and a plurality of individual waveguides 10 arrayed thereon. Etching may be performed by either wet etching or dry etching of the IC materials. In a final step, substrate 12 is sawed (diced) to separate the individual IC chips 10 from each other and the wafer. As a result, there is no sawing of the individual IC structures on the wafer, as sawing is localized only to substrate 12. In a preferred embodiment substrate 12 is formed as a silicon wafer, an easy to saw material resulting in isolated individual chips 10 as shown in FIG. 1C.

While there have been shown and described and pointed out fundamental novel features of the invention as applied to preferred embodiments thereof, it will be understood that various omissions and substitutions and changes in the form and details of the disclosed invention may be made by those skilled in the art without departing from the spirit and scope of the invention. It is the intention therefore, to be limited only as indicated by the scope of the claims appended hereto.

What is claimed is:

1. A method for separating silica waveguides, said waveguides comprising a wafer, and IC material disposed on said wafer, comprising the steps of:
forming streets between adjacent waveguides on the wafer; and
dicing said wafer along said streets.

2. The method of claim 1, wherein said IC chip material includes a first cladding layer disposed on said wafer, a second cladding layer disposed on said first cladding layer and a core layer disposed between said first cladding layer and said second cladding layer.

3. The method of claim 1, wherein said wafer is formed of silicon.

4. The method of claim 1, further comprising the steps of photolitographing said IC chip material in a pattern corresponding to said streets; and
etching said streets to said wafer.

5. The method of claim 4, wherein said etching is performed utilizing a wet etching process.

6. The method of claim 4, wherein said etching process is a dry etching process.
